(19) United States
(12) Patent Application Publication
(10) Pub. No.: US 2026/0186042 A1
(43) Pub. Date: Jul. 2, 2026

(54) CABLE STATUS DETECTION CIRCUIT

(71) Applicant: NOREL SYSTEMS LIMITED, Tianjin (CN)

(72) Inventors: Jinping MAO, Tianjin (CN); Peng SHI, Tianjin (CN); Meng CUI, Tianjin (CN); Ting WU, Tianjin (CN)

(21) Appl. No.: 19/552,139

(22) Filed: Feb. 27, 2026

Related U.S. Application Data
(63) Continuation of application No. PCT/CN2024/106316, filed on Jul. 19, 2024.

(30) Foreign Application Priority Data
Aug. 30, 2023 (CN) 202311110651.1

(51) Int. Cl. G01R 31/08; G01R 19/165

(52) U.S. Cl. CPC G01R 31/083; G01R 19/16576; G01R 31/088

(57) ABSTRACT

A cable status detection circuit comprises an on-chip termination resistor module, a termination discharge module, a status detection signal transmission module, and a status detection signal sampling and judgment module. Among them, the on-chip termination resistor module provides a termination resistor matching the transmission line; the termination discharge module discharges the high-speed interface of the chip to the ground before cable status detection; the status detection signal transmission module is responsible for sending detection signals during cable status detection; and the status detection signal sampling and judgment module samples the voltage status of the high-speed interface after the status detection signal transmission module sends the detection signals, judges the cable status based on the sampling data results, and locates the fault position.

### CROSS-REFERENCE TO RELATED APPLICATION

This application is a continuation application of International Patent Application No. PCT/CN 2024/106316, filed on Jul. 19, 2024, which itself claims priority to and benefit of Chinese Patent Application No. 202311110651.1, filed on Aug. 30, 2023 in the State Intellectual Property Office of P. R. China. The disclosure of each of the above applications is incorporated herein by reference in its entirety.

### TECHNICAL FIELD

The present invention relates to a cable detection circuit, in particular to the detection of cable open circuits, short circuits, and the positioning of fault positions.

### BACKGROUND ART

With the continuous development of the integrated circuit industry, the requirements for the safety performance of chips are increasingly high. Especially in recent years, with the rapid development of automotive chips, automotive chips have higher requirements than ordinary commercial chips, comprising higher requirements for safety and self-testing. In particular, for high-speed interfaces, the detection of cable status is extremely important. A common cable status detection circuit is to add two low-speed interfaces on the chip in addition to the high-speed interface to detect the status of high-speed signal lines. However, this increases the cost for chips with originally tight pin resources, and such a detection circuit cannot locate the fault position, but can only detect whether the cable is open-circuited or short-circuited (to the power supply or ground).

### SUMMARY

The technical problem to be solved by the present invention is to detect the cable status (comprising short circuits, open circuits, and fault position positioning) through the high-speed interface without adding test pins in a high-speed signal transmission system.

The technical solution adopted by the present invention to solve the technical problem is as follows:

As a cable status detection circuit of the present invention, it comprises an on-chip termination resistor module, a termination discharge module, a status detection signal transmission module, and a status detection signal sampling and judgment module. The on-chip termination resistor module is connected to the termination discharge module, the status detection signal transmission module, and the status detection signal sampling and judgment module, and all of them are connected to the high-speed interface. The on-chip termination resistor module provides a termination resistor; the termination discharge module can discharge the high-speed interface of the chip to the ground; the status detection signal transmission module can send status detection signals; and the status detection signal sampling and judgment module can sample the voltage of the high-speed interface.

Preferably, the cable status detection circuit performs cable status detection only through the high-speed interface, without using other interfaces.

Preferably, the termination resistor provided by the on-chip termination resistor module matches the cable impedance.

Preferably, the cable status detection circuit can work in the transmission mode of coaxial cables or differential cables.

Preferably, the status detection signal sampling and judgment module comprises a comparator; the status detection signal sampling and judgment module compares the sampled voltage signal of the high-speed interface with a preset threshold voltage through the comparator and outputs the result, judges the impedance matching degree between the cable resistance and the on-chip termination resistor module based on the output result, and further judges the cable fault type.

Preferably, the cable fault types comprise one or more of the following: differential P-terminal short circuit, differential P-terminal open circuit, differential N-terminal short circuit, differential N-terminal open circuit, short circuit between differential P-terminal and N-terminal, coaxial P-terminal short circuit, and coaxial P-terminal open circuit.

Preferably, the status detection signal sampling and judgment module locates the fault position according to the time interval during which the output value of the comparator changes.

Preferably, the cable status detection circuit can work at the transmitting end or receiving end of a high-speed circuit.

The beneficial effects of the present invention are that the cable status is detected directly through the high-speed interface, and the fault position of the cable is located. The circuit has a simple structure and is easy to integrate.

### BRIEF DESCRIPTION OF DRAWINGS

The present invention will be further described below with reference to the accompanying drawings and embodiments.

FIG. 1 is the overall module diagram of the present invention.

FIG. 2 is a schematic diagram of fault injection at the P-terminal of a differential cable.

FIG. 3 is a schematic diagram of fault injection at the N-terminal of a differential cable.

FIG. 4 is a schematic diagram of fault injection between the P-terminal and N-terminal of a differential cable.

FIG. 5 is a schematic diagram of fault injection at the P-terminal of a coaxial cable.

FIG. 6 is a schematic diagram of the comparator in the status detection signal sampling and judgment module.

FIG. 7 is a schematic diagram of the output of the status detection signal sampling and judgment module under open circuit at the P/N terminal output.

FIG. 8 is a schematic diagram of the output of the status detection signal sampling and judgment module under short circuit of the P/N terminal output to the power supply.

FIG. 9 is a schematic diagram of the output of the status detection signal sampling and judgment module after the P-terminal sends a status detection signal under short circuit between the P-terminal and N-terminal outputs.

FIG. 10 is a schematic diagram of the output of the status detection signal sampling and judgment module after the N-terminal sends a status detection signal under short circuit between the P-terminal and N-terminal outputs.

Wherein:
101 On-chip termination resistor module (P-terminal)
102 Termination discharge module (P-terminal)
103 Status detection signal transmission module (P-terminal)
104 Status detection signal sampling and judgment module (P-terminal)
105 P-terminal cable
106 Remote termination resistor (P-terminal)
1 Control signal for the termination discharge module (P-terminal)
2 Control signal for the termination resistor, status detection signal transmission module, and status detection signal sampling and judgment module (P-terminal)
C11 Proximal termination capacitor (P-terminal)
C12 Remote termination capacitor (P-terminal)
201 On-chip termination resistor module (N-terminal)
202 Termination discharge module (N-terminal)
203 Status detection signal transmission module (N-terminal)
204 Status detection signal sampling and judgment module (N-terminal)
205 N-terminal cable
206 Remote termination resistor (N-terminal)
3 Control signal for the termination discharge module (N-terminal)
4 Control signal for the termination resistor, status detection signal transmission module, and status detection signal sampling and judgment module (N-terminal)
C21 Proximal termination capacitor (N-terminal)
C22 Remote termination capacitor (N-terminal)
RT Off-chip termination resistor when the N-terminal is connected to a coaxial cable

### DETAILED DESCRIPTION OF EMBODIMENTS

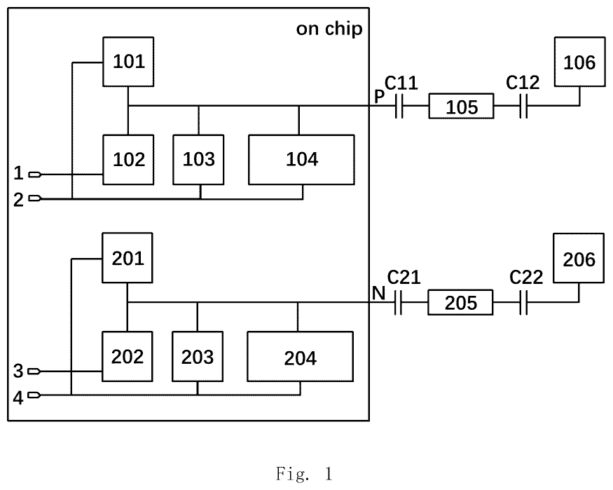

The present invention provides a cable status detection circuit, as shown in FIG. 1.

The modules comprised are: an on-chip termination resistor module 101 (201), a termination discharge module 102 (202), a status detection signal transmission module 103 (203), and a status detection signal sampling and judgment module 104 (204).

Connection mode: Control signal 1 (3) is connected to the termination discharge module 102 (202) to control the termination discharge module; control signal 2 (4) is used to control the on-chip termination resistor module 101 (201), the status detection signal transmission module 103 (203), and the status detection signal sampling and judgment module 104 (204). The on-chip termination resistor module 101 (201), the termination discharge module 102 (202), the status detection signal transmission module 103 (203), and the status detection signal sampling and judgment module 104 (204) are simultaneously connected to the high-speed interface.

### Working Principle

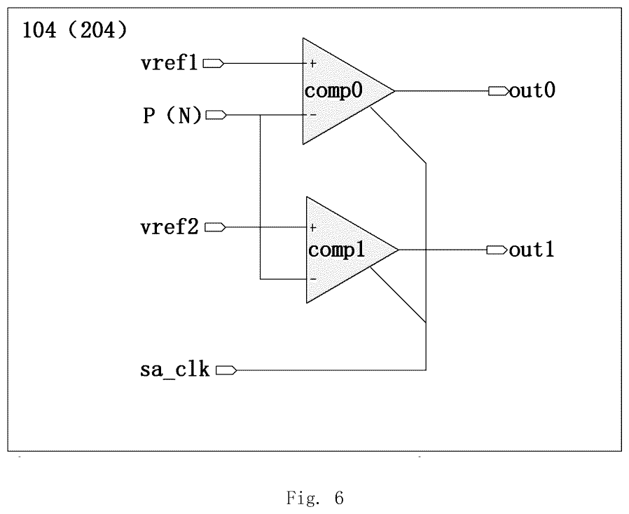

The characteristic impedance of common high-speed signal transmission lines is 50Ω. The transmission line and the high-speed interface are connected through capacitors for AC coupling. According to the signal transmission theory, if the impedance is continuous, a voltage close to ½ of the power supply voltage will be observed at the high-speed interface. Therefore, the impedance of the on-chip termination resistor module 101 (201) used in this cable status detection circuit is 50Ω. During cable status detection, the output voltage of the high-speed interface is pulled to the ground through the termination discharge module 102 (202), then the termination discharge module 102 (202) is turned off through control signal 1 (3), and the status detection signal transmission module 103 (203) and the on-chip termination resistor module 101 (201) are turned on through control signal 2 (4), so that the 50Ω termination resistor is connected to the power supply. When the on-chip termination resistor module 101 (201) is turned on, the status detection signal sampling and judgment module 104 (204) is also enabled to sample the voltage at the high-speed interface and output the comparison result. The frequency of the sampling clock (sa_clk) can be determined according to the accuracy required for locating the fault position; the higher the frequency, the higher the accuracy. The status detection signal sampling and judgment module 104 (204) comprises a comparator, which has two preset threshold voltages (as shown in FIG. 6), namely vref1 (less than ½ of the power supply voltage) and vref2 (greater than ½ of the power supply voltage), and different threshold voltages can be set according to actual applications. The status detection signal sampling and judgment module 104 (204) compares the sampled voltage value of the high-speed interface with the threshold voltages through the comparator and outputs the comparison result. The status detection signal sampling and judgment module 104 (204) judges the cable status based on the output value of the voltage comparator: if the characteristic impedance of the transmission line matches that of the on-chip termination resistor module 101 (201), the output of the comparator in the status detection signal sampling and judgment module 104 (204) for sampling and comparison with vref1 is 1, and the output of the comparator for sampling and comparison with vref2 is 0; if the characteristic impedance of the transmission line is higher than that of the on-chip termination resistor module 101 (201), the output of the comparator for sampling and comparison with vref1 is 1, and the output of the comparator for sampling and comparison with vref2 is 1; if the characteristic impedance of the transmission line is lower than that of the on-chip termination resistor module 101 (201), the output of the comparator for sampling and comparison with vref1 is 0, and the output of the comparator for sampling and comparison with vref2 is 0. For a specific transmission cable, the transmission delay is fixed; therefore, the fault position of the cable can be determined according to the time interval during which the output value of the comparator in the status detection signal sampling and judgment module 104 (204) changes. The longer the time interval during which the output value of the comparator changes, the farther the cable fault position is from the high-speed interface.

This cable status detection circuit can be applied to high-speed interfaces connected through coaxial cables or differential cables.

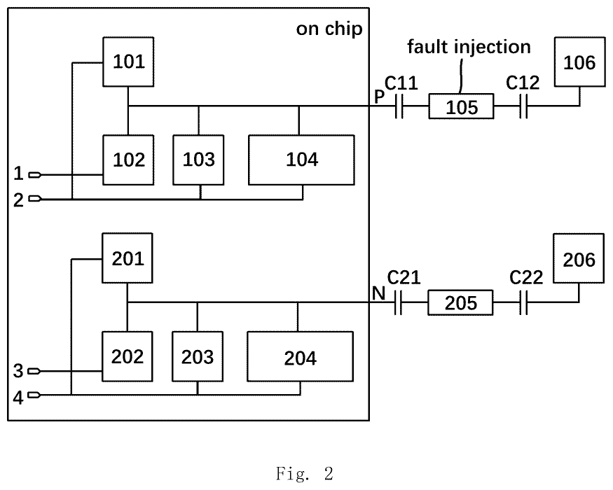

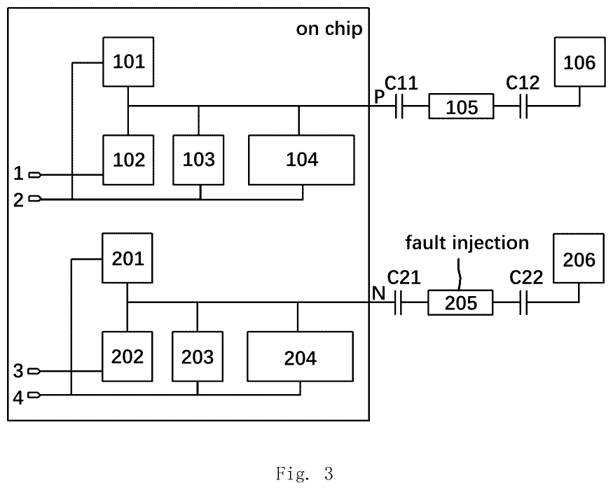

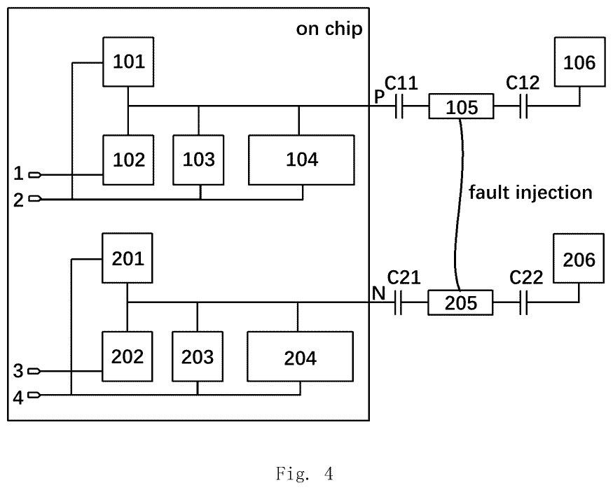

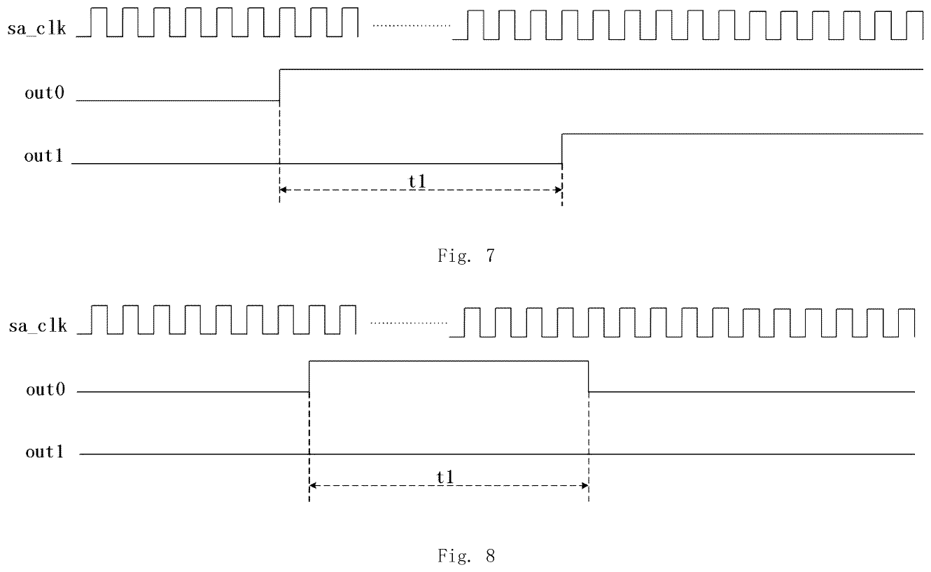

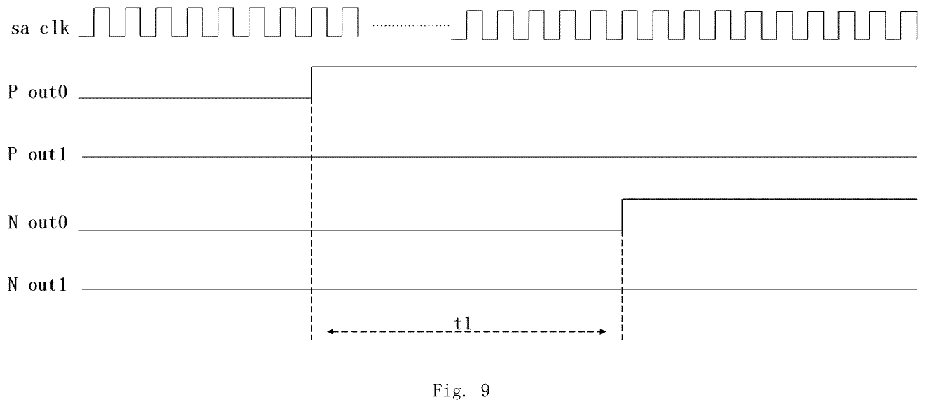

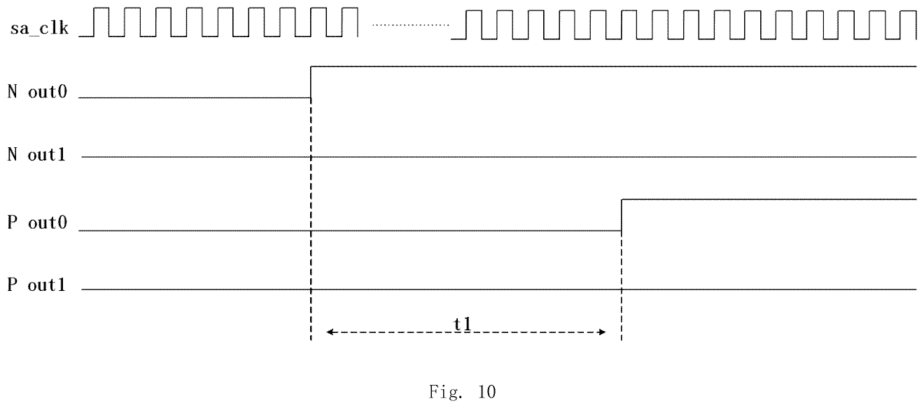

The application examples for different fault injections in differential cable connections are as follows:
1. As shown in FIG. 2, an open-circuit fault is injected into the P-terminal transmission line 105. After the P-terminal on-chip termination resistor module 101 is connected to the power supply and the P-terminal status detection signal transmission module 103 sends a detection signal, the P-terminal status detection signal sampling and judgment module 104 samples the voltage status at the high-speed interface in real time. Since the transmission line 105 is open-circuited at this time, the signal remains continuous before being transmitted to the fault injection point, and the voltage observed at the high-speed interface is close to ½ of the power supply voltage. Therefore, the output of the comparator in the status detection signal sampling and judgment module 104 for comparison with the reference voltage vref1 is 1, and the output of the comparator for comparison with the reference voltage vref2 is 0. When the signal is transmitted to the fault injection point, signal reflection occurs, and the voltage observed at the high-speed interface is higher than the reference voltage vref2. At this time, the output of the comparator for comparison with the reference voltage vref1 is 1, and the output of the comparator for comparison with the reference voltage vref2 is 1. The position of the fault injection point can be determined according to the time interval t1 between the moment when the output of the comparator (for comparison with the reference voltage vref1) in the status detection signal sampling and judgment module 104 changes from 0 to 1 and the moment when the output of the comparator (for comparison with the reference voltage vref2) changes from 0 to 1 (as shown in FIG. 7). The longer t1 is, the farther the fault injection point is from the high-speed interface.
2. As shown in FIG. 2, a short-circuit fault (short circuit to the power supply or ground) is injected into the P-terminal transmission line 105. After the P-terminal on-chip termination resistor module 101 is connected to the power supply and the P-terminal status detection signal transmission module 103 sends a detection signal, the P-terminal status detection signal sampling and judgment module 104 samples the voltage status at the high-speed interface in real time. Since the transmission line 105 is short-circuited at this time, the signal remains continuous before being transmitted to the fault injection point, and the voltage observed at the high-speed interface is close to ½ of the power supply voltage. Therefore, the output of the comparator in the status detection signal sampling and judgment module 104 for comparison with the reference voltage vref1 is 1, and the output of the comparator for comparison with the reference voltage vref2 is 0. When the signal is transmitted to the fault injection point, signal reflection occurs, and the voltage observed at the high-speed interface is lower than the reference voltage vref1. At this time, the output of the comparator for comparison with the reference voltage vref1 is 0, and the output of the comparator for comparison with the reference voltage vref2 is 0. The position of the fault injection point can be determined according to the time interval t1 between the moment when the output of the comparator (for comparison with the reference voltage vref1) in the status detection signal sampling and judgment module 104 changes from 0 to 1 and the moment when the output of the comparator (for comparison with the reference voltage vref1) changes from 1 to 0 (as shown in FIG. 8). The longer t1 is, the farther the fault injection point is from the high-speed interface.
3. As shown in FIG. 3, an open-circuit fault is injected into the N-terminal transmission line 205. After the N-terminal on-chip termination resistor module 201 is connected to the power supply and the N-terminal status detection signal transmission module 203 sends a detection signal, the N-terminal status detection signal sampling and judgment module 204 samples the voltage status at the high-speed interface in real time. Since the transmission line 205 is open-circuited at this time, the signal remains continuous before being transmitted to the fault injection point, and the voltage observed at the high-speed interface is close to ½ of the power supply voltage. Therefore, the output of the comparator in the status detection signal sampling and judgment module 204 for comparison with the reference voltage vref1 is 1, and the output of the comparator for comparison with the reference voltage vref2 is 0. When the signal is transmitted to the fault injection point, signal reflection occurs, and the voltage observed at the high-speed interface is higher than the reference voltage vref2. At this time, the output of the comparator for comparison with the reference voltage vref1 is 1, and the output of the comparator for comparison with the reference voltage vref2 is 1. The position of the fault injection point can be determined according to the time interval t1 between the moment when the output of the comparator (for comparison with the reference voltage vref1) in the status detection signal sampling and judgment module 204 changes from 0 to 1 and the moment when the output of the comparator (for comparison with the reference voltage vref2) changes from 0 to 1 (as shown in FIG. 7). The longer t1 is, the farther the fault injection point is from the high-speed interface.
4. As shown in FIG. 3, a short-circuit fault (short circuit to the power supply or ground) is injected into the N-terminal transmission line 205. After the N-terminal on-chip termination resistor module 201 is connected to the power supply and the N-terminal status detection signal transmission module 203 sends a detection signal, the N-terminal status detection signal sampling and judgment module 204 samples the voltage status at the high-speed interface in real time. Since the transmission line 205 is short-circuited at this time, the signal remains continuous before being transmitted to the fault injection point, and the voltage observed at the high-speed interface is close to ½ of the power supply voltage. Therefore, the output of the comparator in the status detection signal sampling and judgment module 204 for comparison with the reference voltage vref1 is 1, and the output of the comparator for comparison with the reference voltage vref2 is 0. When the signal is transmitted to the fault injection point, signal reflection occurs, and the voltage observed at the high-speed interface is lower than the reference voltage vref1. At this time, the output of the comparator for comparison with the reference voltage vref1 is 0, and the output of the comparator for comparison with the reference voltage vref2 is 0. The position of the fault injection point can be determined according to the time interval t1 between the moment when the output of the comparator (for comparison with the reference voltage vref1) in the status detection signal sampling and judgment module 204 changes from 0 to 1 and the moment when the output of the comparator (for comparison with the reference voltage vref2) changes from 1 to 0 (as shown in FIG. 8). The longer t1 is, the farther the fault injection point is from the high-speed interface.
5. As shown in FIG. 4, a short-circuit fault is injected between the P-terminal transmission line 105 and the N-terminal transmission line 205. After the P-terminal on-chip termination resistor module 101 is connected to the power supply and the P-terminal status detection signal transmission module 103 sends a detection signal, the P-terminal status detection signal sampling and judgment module 104 samples the voltage status at the high-speed interface in real time. Since there is a short circuit between the transmission line 105 and the transmission line 205 at this time, the signal remains continuous before being transmitted to the fault injection point, and the voltage observed at the high-speed interface is close to ½ of the power supply voltage. Therefore, the output of the comparator in the status detection signal sampling and judgment module 104 for comparison with the reference voltage vref1 is 1, and the output of the comparator for comparison with the reference voltage vef2 is 0. When the signal is transmitted to the fault injection point, a signal is observed at the N-terminal of the high-speed interface. At this time, the output of the comparator in the status detection signal sampling and judgment module 204 for comparison with the reference voltage vref1 is 1, and the output of the comparator for comparison with the reference voltage vref2 is 0. The position of the fault injection point can be determined according to the time interval t1 between the moment when the output of the comparator (for comparison with the reference voltage vref1) in the status detection signal sampling and judgment module 104 changes from 0 to 1 and the moment when the output of the comparator (for comparison with the reference voltage vref1) in the status detection signal sampling and judgment module 204 changes from 0 to 1 (as shown in FIG. 9). The longer t1 is, the farther the fault injection point is from the high-speed interface.
6. As shown in FIG. 4, a short-circuit fault is injected between the P-terminal transmission line 105 and the N-terminal transmission line 205. After the N-terminal on-chip termination resistor module 201 is connected to the power supply and the N-terminal status detection signal transmission module 203 sends a detection signal, the N-terminal status detection signal sampling and judgment module 204 samples the voltage status at the high-speed interface in real time. Since there is a short circuit between the transmission line 105 and the transmission line 205 at this time, the signal remains continuous before being transmitted to the fault injection point, and the voltage observed at the high-speed interface is close to ½ of the power supply voltage. Therefore, the output of the comparator in the status detection signal sampling and judgment module 204 for comparison with the reference voltage vref1 is 1, and the output of the comparator for comparison with the reference voltage vef2 is 0. When the signal is transmitted to the fault injection point, a signal is observed at the P-terminal of the high-speed interface. At this time, the output of the comparator in the status detection signal sampling and judgment module 104 for comparison with the reference voltage vref1 is 1, and the output of the comparator for comparison with the reference voltage vref2 is 0. The position of the fault injection point can be determined according to the time interval t1 between the moment when the output of the comparator (for comparison with the reference voltage vref1) in the status detection signal sampling and judgment module 204 changes from 0 to 1 and the moment when the output of the comparator (for comparison with the reference voltage vref1) in the status detection signal sampling and judgment module 104 changes from 0 to 1 (as shown in FIG. 10). The longer t1 is, the farther the fault injection point is from the high-speed interface.

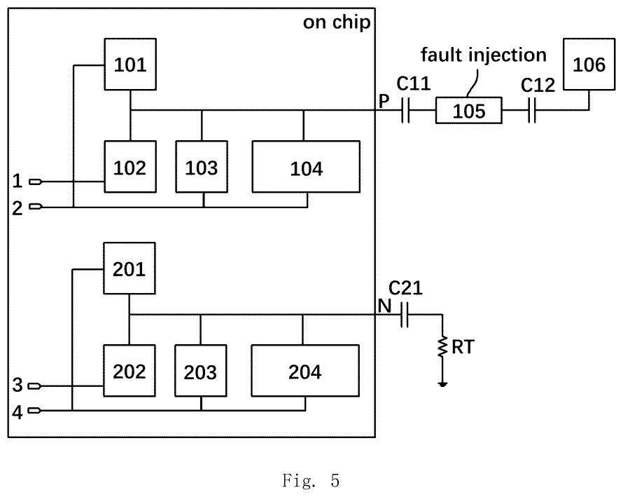

The application examples for different fault injections in coaxial cable connections are as follows:
1. As shown in FIG. 5, where RT is a termination resistor used for termination resistor matching. An open-circuit fault is injected into the P-terminal transmission line 105. After the P-terminal on-chip termination resistor module 101 is connected to the power supply and the P-terminal status detection signal transmission module 103 sends a detection signal, the P-terminal status detection signal sampling and judgment module 104 samples the voltage status at the high-speed interface in real time. Since the transmission line 105 is open-circuited at this time, the signal remains continuous before being transmitted to the fault injection point, and the voltage observed at the high-speed interface is close to ½ of the power supply voltage. Therefore, the output of the comparator in the status detection signal sampling and judgment module 104 for comparison with the reference voltage vref1 is 1, and the output of the comparator for comparison with the reference voltage vref2 is 0. When the signal is transmitted to the fault injection point, signal reflection occurs, and the voltage observed at the high-speed interface is higher than the reference voltage vref2. At this time, the output of the comparator for comparison with the reference voltage vref1 is 1, and the output of the comparator for comparison with the reference voltage vref2 is 1. The position of the fault injection point can be determined according to the time interval t1 between the moment when the output of the comparator (for comparison with the reference voltage vref1) in the status detection signal sampling and judgment module 104 changes from 0 to 1 and the moment when the output of the comparator (for comparison with the reference voltage vref2) changes from 0 to 1 (as shown in FIG. 7). The longer t1 is, the farther the fault injection point is from the high-speed interface.
2. As shown in FIG. 5, a short-circuit fault (short circuit to the power supply or ground) is injected into the P-terminal transmission line 105. After the P-terminal on-chip termination resistor module 101 is connected to the power supply and the P-terminal status detection signal transmission module 103 sends a detection signal, the P-terminal status detection signal sampling and judgment module 104 samples the voltage status at the high-speed interface in real time. Since the transmission line 105 is short-circuited at this time, the signal remains continuous before being transmitted to the fault injection point, and the voltage observed at the high-speed interface is close to ½ of the power supply voltage. Therefore, the output of the comparator in the status detection signal sampling and judgment module 104 for comparison with the reference voltage vref1 is 1, and the output of the comparator for comparison with the reference voltage vref2 is 0. When the signal is transmitted to the fault injection point, signal reflection occurs, and the voltage observed at the high-speed interface is lower than the reference voltage vref1. At this time, the output of the comparator for comparison with the reference voltage vref1 is 0, and the output of the comparator for comparison with the reference voltage vref2 is 0. The position of the fault injection point can be determined according to the time interval t1 between the moment when the output of the comparator (for comparison with the reference voltage vref1) in the status detection signal sampling and judgment module 104 changes from 0 to 1 and the moment when the output of the comparator (for comparison with the reference voltage vref1) changes from 1 to 0 (as shown in FIG. 8). The longer t1 is, the farther the fault injection point is from the high-speed interface.

The above are only preferred embodiments of the present invention and are not intended to limit the present invention in any form. Any simple modifications, equivalent changes, and modifications made to the above embodiments according to the technical essence of the present invention still fall within the scope of the technical solution of the present invention.

In conclusion, the present invention fully meets the needs of industrial development in terms of structural design, practicality in use, and cost-effectiveness. The disclosed structure also has an unprecedented innovative structure, with novelty, inventiveness, and practicality, which meets the requirements for utility model patents. Therefore, an application is filed in accordance with the law.

What is claimed is:

1. A cable status detection circuit, comprising an on-chip termination resistor module, a termination discharge module, a status detection signal transmission module, and a status detection signal sampling and judgment module, characterized in that:
the on-chip termination resistor module is connected to the termination discharge module, the status detection signal transmission module, and the status detection signal sampling and judgment module, and all of them are connected to the high-speed interface;
the on-chip termination resistor module provides a termination resistor;
the termination discharge module can discharge the high-speed interface of the chip to the ground;
the status detection signal transmission module can send status detection signals;
the status detection signal sampling and judgment module can sample and judge the voltage of the high-speed interface.

2. The cable status detection circuit according to claim 1, characterized in that:
the cable status detection circuit performs cable status detection only through the high-speed interface, without using other interfaces.

3. The cable status detection circuit according to claim 1, characterized in that:
the termination resistor provided by the on-chip termination resistor module matches the cable impedance.

4. The cable status detection circuit according to claim 1, characterized in that:
the cable status detection circuit can work in the transmission mode of coaxial cables or differential cables.

5. The cable status detection circuit according to claim 1, characterized in that:
the status detection signal sampling and judgment module comprises a comparator;
The status detection signal sampling and judgment module compares the sampled voltage signal of the high-speed interface with a preset threshold voltage through the comparator and outputs the result, judges the impedance matching degree between the cable resistance and the on-chip termination resistor module based on the output result, and further judges the cable fault type.

6. The cable status detection circuit according to claim 5, characterized in that:
the cable fault types comprise one or more of the following: differential P-terminal short circuit, differential P-terminal open circuit, differential N-terminal short circuit, differential N-terminal open circuit, short circuit between differential P-terminal and N-terminal, coaxial P-terminal short circuit, and coaxial P-terminal open circuit.

7. The cable status detection circuit according to claim 1, characterized in that:
the status detection signal sampling and judgment module locates the fault position according to the time interval during which the output value of the comparator changes.

8. The cable status detection circuit according to claim 1, characterized in that:
the cable status detection circuit can work at the transmitting end or receiving end of a high-speed circuit.
